(19) United States
(12) Patent Application Publication
(10) Pub. No.: US 2022/0025259 A1
(43) Pub. Date: Jan. 27, 2022

(54) Quantum-Dot Light Emitting Diode and Packaging Method Thereof

(71) Applicant: Taiwan Nanocrystals Inc., Tainan City (TW)

(72) Inventors: Chih-Jung Chen, Tainan City (TW); Ray-Kuang Chiang, Tainan City (TW)

(21) Appl. No.: 17/376,093

(22) Filed: Jul. 14, 2021

(30) Foreign Application Priority Data
Jul. 21, 2020 (CN) 202010703828.9

(51) Int. Cl. C09K 11/88; C09K 11/56; H01L 31/0216; G03F 7/16; G03F 7/40; G03F 7/029; G03F 7/09

(52) U.S. Cl. CPC C09K 11/883; C09K 11/565; H01L 31/02164; H01L 51/502; G03F 7/40; G03F 7/029; G03F 7/09; G03F 7/16

(57) ABSTRACT

A quantum-dot light emitting diode includes, in sequential order from bottom to top, a LED light source, a quantum-dot photoresist layer and a barrier layer. The quantum-dot photoresist layer has a thickness lower than 20 μm and is formed by specific material, so as to decrease a step difference between the quantum-dot photoresist layer and a light exit surface of the LED light source, to improve coating property of the barrier material and make sure that the coating of the barrier material can be implemented by dry coating or wet coating; the barrier material is not easy to crack to cause air leakage and oxidation because of thermal expansion and contraction, so as to increase the success rate of side packaging and the reliability of the process, and extend the reliability of the material.

### BACKGROUND OF THE PRESENT INVENTION

### Field of Invention

The present invention relates to a field of quantum-dot light emitting diode, and more particularly to a quantum-dot light emitting diode and a packaging method thereof.

### Description of Related Arts

The conventional architecture of chip scale package (CSP) mostly has a one-side or five-side light-emitting structure to achieve the purpose of increasing luminance efficiency, decreasing amount of phosphor, and reducing thickness. However, the concentration of quantum dot in conventional organic silicone resin and epoxy resin encapsulant is prevented from being too high, for example, the concentration needs to be lower 5 wt % preferably; otherwise, the adhesion of the encapsulant may be impacted. Furthermore, the thickness of the encapsulant is generally greater than 30 μm, and it reduces light absorption efficiency.

For the quantum-dot LED light source, blocking moisture and oxygen is extremely important, but the conventional packaging technology is unable to prevent moisture and oxygen from invading, and it results in poor component reliability. In a condition that the moisture-oxygen-blocking layer is made by vapor deposition technology (evaporation or sputtering) in the existing conventional CSP architecture, the vertical periphery planes of component cause a too large step difference, so the epitaxy effect is impacted; the coverage of the material at the corners is not good enough, so the material is easy to fall off; the thick thickness of the side of the component may greatly reduce the success rate of coating the moisture-oxygen-blocking material on the side of the component, so the penetration of moisture and oxygen is easy to occur.

### SUMMARY OF THE PRESENT INVENTION

In order to solve aforementioned conventional problems, a first aspect of the present invention is to provide a quantum-dot light emitting diode, and the quantum-dot light emitting diode includes, in sequential order from bottom to top, a LED light source, a quantum-dot photoresist layer and a barrier layer.

According to a preferable technical solution, the quantum-dot photoresist layer can have a thickness lower than 20 μm.

According to a preferable technical solution, a length of the quantum-dot photoresist layer is smaller than a length of the LED light source by 0.1 μm to 100 μm, and a width of the quantum-dot photoresist layer is smaller than a width of the LED light source by 0.1 μm to 100 μm.

According to a preferable technical solution, an edge structure at junction of the quantum-dot photoresist layer and the LED light source is one of a perpendicular structure, an inclined structure, a circular-arc structure and a combination thereof.

According to a preferable technical solution, the quantum-dot photoresist layer includes quantum dots and a photoresist material, and a weight ratio of the quantum dots and the photoresist material is in a range of 1:2 to 1:100.

According to a preferable technical solution, the quantum-dot photoresist layer is inlaid in the barrier layer.

According to a preferable technical solution, the quantum-dot light emitting diode can include a protective layer disposed on the barrier layer.

According to a preferable technical solution, the quantum-dot light emitting diode can include a second light-shielding layer disposed around the protective layer.

According to a preferable technical solution, the quantum-dot light emitting diode can include a first light-shielding layer disposed around the LED light source, and the first light-shielding layer is connected to the LED light source, the barrier layer and the second light-shielding layer in sequential order.

In order to solve aforementioned conventional problems, a second aspect of the present invention is to provide a packaging method of quantum-dot light-emitting diode to package the aforementioned quantum-dot light emitting diode.

According to above-mentioned contents, the present invention has at least one of the following beneficial effects.

First, the present invention replaces the conventional organic silicone resin and epoxy resin by the quantum-dot photoresist layer, so that the property of the quantum-dot photoresist layer can be adjusted by the barrier layer and the light shielding layer, the solids content of the quantum dots in the quantum-dot photoresist layer can be improved and thermal expansion coefficient can be reduced.

Secondly, the present invention can form the quantum dot photoresist emission layer by the yellow light technology, to limit the size relationship between the light exit area of the LED light source and the light emitting area of the quantum-dot photoresist layer, so that the side space of the quantum-dot photoresist layer and the LED light source can be used to support the barrier material coated in sequential process.

Thirdly, the present invention uses the quantum-dot photoresist layer having the thickness lower than 20 μm and formed by specific material, to decrease the step difference between the quantum-dot photoresist layer and the light exit surface of the LED light source, so that the coating property of the barrier material can be improved to make sure that the coating of the barrier material can be implemented by dry coating or wet coating and make the barrier material not easy to crack due to thermal expansion and contraction, thereby preventing air leakage and oxidation and increasing successful rate of side packaging method.

Fourthly, the structure at the specific junction of the quantum-dot photoresist layer and the LED light source of the present invention can be adjusted through yellow light process and the material of the quantum-dot photoresist layer, so as to improve side coverage of the barrier material and make the barrier material be more easily coated in sequential process, thereby increasing process reliability and extending material reliability.

Fifthly, the present invention can use the second light-shielding layer disposed on the barrier material, to solve the light leakage problem caused by the size difference between the light exit area of the LED light source and the light emitting area of the quantum-dot photoresist layer; furthermore, the periphery of the LED light source and the barrier layer can be enclosed by the first light-shielding layer, to realize the front-side single-sided luminous design to increase the front-side emission efficiency.

### BRIEF DESCRIPTION OF THE DRAWINGS

The structure, operating principle and effects of the present invention will be described in detail by way of various embodiments which are illustrated in the accompanying drawings.

FIG. 1 is a schematic structural perspective view of a quantum-dot light emitting diode, according to a first embodiment of the present invention.

FIG. 2 is a schematic structural cross-sectional view of a quantum-dot light emitting diode, according to a first embodiment of the present invention, wherein the cross-sectional view is taken along A-A′ of FIG. 1.

FIG. 3 is a schematic structural cross-sectional view of a quantum-dot light emitting diode, according to a second embodiment of the present invention.

FIG. 4 is a schematic structural cross-sectional view of a quantum-dot light emitting diode, according to a third embodiment of the present invention.

FIG. 5 is a schematic structural cross-sectional view of a quantum-dot light emitting diode, according a fourth embodiment of the present invention.

FIG. 6 is a schematic structural cross-sectional view of a quantum-dot light emitting diode, according to a fifth embodiment of the present invention, wherein the cross-sectional view is taken along B-B′ of FIG. 7.

FIG. 7 is a top view of a quantum-dot light emitting diode, according to a fifth embodiment of the present invention.

FIG. 8 is an electroluminescence spectrogram of a quantum-dot light emitting diode, according to a fifth embodiment of the present invention.

FIG. 9 is a color gamut diagram of a quantum-dot light emitting diode, according to a fifth embodiment of the present invention.

### DETAILED DESCRIPTION OF THE PREFERRED EMBODIMENT

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the scope of the present invention in any way. Further modifications to the disclosed embodiments, as well as other embodiments, are also included within the scope of the appended claims. Unless otherwise defined, all terms (including technical and scientific terms) used herein have the same meaning as commonly understood by one of ordinary skill in the art to which this invention belongs. When there is a conflict between the definition in specification and the common definition, the term is interpreted according to the definition in this specification.

The technical features of technical solution of the present invention will be described in detail by way of various embodiments. It will be understood that the embodiments of the present invention described herein are merely exemplary and not all possible embodiments, and a person skilled in the art may effortlessly make many variations and modification to obtain another embodiment without departing from the spirit and scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms “up” and “down” defined in the present invention mean that when the reader is facing the drawing, the upper side of the drawing viewed by the reader is “up” and the lower side of the drawing viewed by the reader is “down”, and the terms “up’ and “down” are not intended to limit the product structure of the present invention.

The terms “left” and “right” defined in the present invention mean that when the reader is facing the drawing, the left side of the drawing viewed by the reader is “left” and the right side of the drawing viewed by the reader is “right”, and the terms “left’ and “right” are not intended to limit the product structure of the present invention.

The terms “top” and “bottom” defined in the present invention means that when the reader is facing the drawing, the top portion of the drawing viewed by the reader is “top” and the bottom portion of the drawing viewed by the reader is “bottom”, and the terms “top’ and “bottom” are not intended to limit the product structure of the present invention.

It will also be understood that when an element is referred to as being “disposed on” or “connected to” another element, it can be directly disposed on or connected to the other element or intervening elements may be present. The connection given herein is fixed connection if not expressly stated.

These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts. As used herein, the singular forms “a”, “an” and “the” are intended to include the plural forms as well, unless the context clearly indicates otherwise.

It is to be acknowledged that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the words “comprise” and “include”, and variations such as “comprises”, “comprising”, “includes”, or “including”, will be acknowledged to imply the inclusion of stated elements but not the exclusion of any other elements.

In order to solve aforementioned problem, a first aspect of the present invention is to provide a quantum-dot light emitting diode including, in sequential order from bottom to top, a LED light source 1, a quantum-dot photoresist layer 2 and a barrier layer 3.

In a preferable implementation, the LED light source 1, the quantum-dot photoresist layer 2 and the barrier layer 3 are fixedly connected to each other.

The fixedly connecting manner used in the present invention is not limited, and various fixedly connecting manner for light-emitting diode known to those skilled in the art, such as adhesive connecting manner or welding connecting manner, can be used in the present invention.

LED Light Source

The shape of the LED light source 1 of the present invention is not limited particularly, for example, the shape of the LED light source 1 can be one of a rectangular shape, a square shape, a circular shape and an elliptic shape.

In a preferable implementation, the shape of the LED light source 1 is a rectangular shape.

In a preferable implementation, the light emitted by the LED light source 1 can be one of ultraviolet light (UV), blue light, green light and red light.

In a preferable implementation, the LED light source 1 emits light with wavelength in a range of 365 nm to 700 nm.

Quantum-Dot Photoresist Layer

In a preferable implementation, the quantum-dot photoresist layer 2 is disposed on the LED light source 1.

In a preferable implementation, the quantum-dot photoresist layer 2 is disposed on a central portion of a top of the LED light source 1.

In a preferable implementation, the quantum-dot photoresist layer 2 has a thickness lower than 20 μm.

In a more preferable implementation, the quantum-dot photoresist layer 2 has a thickness lower than 3 μm.

In a preferable implementation, a length of the quantum-dot photoresist layer 2 is smaller than a length of the LED light source 1 by a 0.1 μm to 100 μm.

In a preferable implementation, a width of the quantum-dot photoresist layer 2 is smaller than a width of the LED light source 1 by a 0.1 μm to 100 μm.

A width of each of the quantum-dot photoresist layer 2 and the LED light source 1 of the present invention is defined as a distance between left and right sides thereof in a horizontal direction parallel to the ground, and a length of each of the quantum-dot photoresist layer 2 and the LED light source 1 is defined as a distance between front and rear sides thereof in a horizontal direction parallel to the ground, and a thickness of the quantum-dot photoresist layer 2 is defined as a distance between top and bottom sides thereof in a vertical direction perpendicular to the ground.

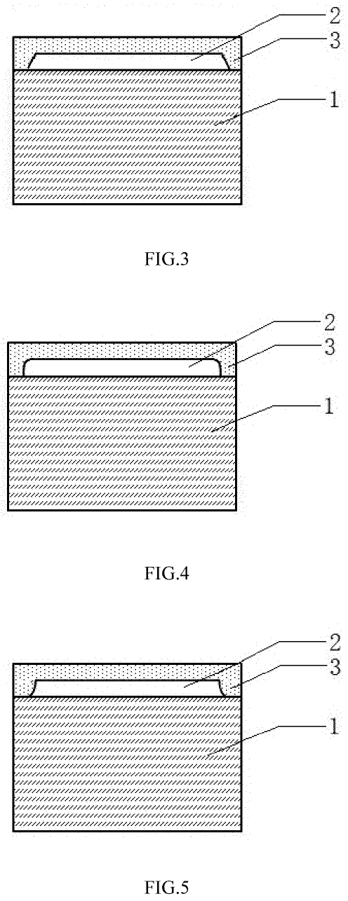

In a preferable implementation, the edge structure at the junction of the quantum-dot photoresist layer 2 and the LED light source 1 is one of a perpendicular structure (as shown in FIG. 2), an inclined structure (as shown in FIG. 3) and a circular-arc structure (as shown in FIG. 4 or FIG. 5).

The edge structure at the junction of the quantum-dot photoresist layer 2 and the LED light source 1 is defined as a structure connecting the periphery of the quantum-dot photoresist layer 2 and the side of the LED light source 1. The perpendicular structure means that the lateral side of the quantum-dot photoresist layer 2 is perpendicular to the top plane of the LED light source 1; the inclined structure means that the lateral side of the quantum-dot photoresist layer 2 is in a plane structure, and an included angle (except 90°) is formed between the lateral side of the quantum-dot photoresist layer 2 and the top plane of the LED light source 1; the circular-arc structure means that the lateral side of the quantum-dot photoresist layer 2 is in a circular-arc structure, and the transition between the side of the quantum-dot photoresist layer 2 and the top plane of LED light source 1 is a circular arc.

In a preferable implementation, the quantum-dot photoresist layer 2 includes quantum dots and photoresist material.

In a preferable implementation, a weight ratio of the quantum dots and the photoresist material is in a range of 1:2 to 1:100.

In a more preferable implementation, a weight ratio of the quantum dots and the photoresist material is in a range of 1:8.7 to 1:94.5.

In a preferable implementation, the quantum dots in the quantum-dot photoresist layer 2 are one of green quantum dots, red quantum dots, blue quantum dots or a combination thereof.

In a preferable implementation, the quantum dots in the quantum-dot photoresist layer 2 are a combination of green quantum dots and red quantum dots.

In a preferable implementation, a weight ratio of the green quantum dots to the red quantum dots is in a range of 1:1 to 3:1.

In a more preferable implementation, a weight ratio of the green quantum dots to red quantum dots is 2:1.

In a preferable implementation, the wavelength of light emitted from the material of the quantum dots in the quantum-dot photoresist layer 2 is in a range of 400 nm to 106 nm.

In a preferable implementation, the quantum dot is in a core-shell structure.

In a preferable implementation, in parts by weight, the quantum dot contains 0.3˜2.8 parts of core material, 0.45˜5.2 parts of shell material, and 0.3˜1.0 parts of ligand.

In a preferable implementation, each of the core material and the shell material is individually selected from the group including the group II-VI, the group III-V, the I-III-VI group and a combination thereof.

In a preferable implementation, the core material is CdSe (CAS No. 1306-24-7), the shell material is ZnS (CAS No. 1314-98-3).

In a preferable implementation, the ligand is selected from a group including octadecylamine (CAS No. 124-30-1), oleylamine (CAS No. 112-90-3), oleic acid (CAS No. 112-80-1), tri-n-octyl phosphine oxide (CAS No. 78-50-2), 3-mercaptopropionic acid (CAS No. 107-96-0), ethylenediaminetetraacetic acid (CAS No. 60-00-4), and a combination thereof.

In a more preferable implementation, the ligand is selected from a group including octadecylamine, oleylamine, oleic acid, and a combination thereof.

The quantum-dot preparation method used in the present invention is not particularly limited, and various quantum-dot preparation methods (such as hot-injection methods,) well known to those skilled in the art can be applied in the present invention.

In a preferable implementation, the photoresist material can be polyacrylate material or epoxy material.

The epoxy material used in the present invention is not particularly limited, and various epoxy materials that can be used for photoresist material and well known to those skilled in the art can be applied in the present invention, for example, the epoxy material can be the SU-8 photoresist of Microchem Corporation in the United States.

In a preferable implementation, in parts by weight, the polyacrylate material contains 8˜10 parts of acrylate monomer, 10˜12 parts of acrylic resin, 60.0˜70.0 parts of solvent, and 1˜2 parts of photoinitiator.

The acrylate monomer used in the present invention is not particularly limited, and various acrylate monomers that can be used for photoresist material and well known to those skilled in the art can be applied to the present invention; for example, the acrylate monomer can be methyl methacrylate (CAS No. 80-62-6). The acrylic resin used in the present invention is not particularly limited, and various acrylic resins that can be used for the photoresist material and well known to those skilled in the art can be applied to the present invention; for example, the acrylic resin can be the acrylic resin of model No. 7536 purchased from BASF. The solvent used in the present invention is not particularly limited, and various solvents that can be used for photoresist material and are well known to those skilled in the art can be applied to the present invention; for example, the solvent can be propylene glycol methyl ether acetate (PGMEA) (CAS No. 108-65-6). The photoinitiator used in the present invention is not particularly limited, and various photoinitiators that can be used for photoresist material and are well known to those skilled in the art can be used in the present invention; for example, the photoinitiator can be 2-benzyl-2-dimethylamino-1-(4-morpholinophenyl) butanone (CAS No. 119313-12-1) or 1-[9-ethyl-6-(2-methylbenzyl)-9H-oxazole-3-base]ethyl ketone 1-(O-acetoxime) (CAS No. 478556-66-0).

In a preferable implementation, the polyacrylate material contains 0˜5 (except 0) parts of scatterer.

In an embodiment, the scatterer can include, but not limited to, ZnO, TiO2, SiO2, BiTiO3, ZrO2.

The preparation method for the quantum-dot photoresist layer 2 used in the present invention is not particularly limited, and various quantum-dot photoresist layer preparation methods well known to those skilled in the art can be applied to the present invention; for example, the quantum dot, the scatterer, the acrylate monomer, and the acrylic resin, and the photoinitiator can be added in the solvent, and the mixture is uniformly blended and stirred, and the quantum-dot photoresist layer can be prepared by coating the mixture.

Barrier Layer

The role of the barrier layer is to block moisture and oxygen, so as to protect the internal quantum-dot photoresist layer and LED light source.

In a preferable implementation, the quantum-dot photoresist layer 2 is inlaid in the barrier layer 3.

In a preferable implementation, the quantum-dot photoresist layer 2 is inlaid at central portion of the bottom of the barrier layer 3.

In a preferable implementation, the barrier layer 3 is disposed on a central portion of the top of the LED light source 1.

In a preferable implementation, the barrier layer 3 is disposed on the central portion of the top of the LED light source 1 by dry coating or wet coating.

The examples of dry coating can include, but not limited to, evaporation method, sputtering method, chemical vapor deposition (CVD) or atomic layer deposition (ALD).

The examples of wet coating can include, but not limited to, spin coating method, screen printing method, blade coating method or immersion method.

In a preferable implementation, the shape and size of the barrier layer 3 are substantially the same as the shape and size of the top of the LED light source 1.

In a preferable implementation, the material of the barrier layer 3 can be inorganic barrier material or organic barrier material.

In another preferred embodiment, the material of the barrier layer 3 is a combination of inorganic barrier material and organic barrier material.

The combination of inorganic barrier material and organic barrier material means that the barrier layer 3 is formed by overlapping inorganic barrier material and organic barrier material, layer by layer; the layer thickness of each of inorganic barrier material and organic barrier material is not particularly limited.

The inorganic barrier material can include, but not limited to, Al2O3, SiO2, ITO graphene, graphene oxide, or I2O3.

The organic barrier material can include, but not limited to, polyacrylate material, epoxy resin, polystyrene, polycarbonate, styrene-acrylonitrile copolymer, or silicone resin.

In a preferable implementation, the thickness of the barrier layer 3 is in a range of 10 nm to 2000 nm.

Protective Layer

In a preferable implementation, a protective layer 5 is disposed on the barrier layer 3.

In a more preferable implementation, the protective layer 5 is disposed on a central portion of a top of the barrier layer 3.

In a preferable implementation, the thickness of the protective layer 5 is in a range of 0.5 μm to 10 μm.

The material of the protective layer 5 of the present invention is not particularly limited, and various materials which can be used for light emitting diode protective layers and are well known to one of ordinary skill in the art can be applied to the present invention;

for example, material of the protective layer can be SiO2 or Al2O3.

Light Shielding Layer

In a preferable implementation, the light shielding layer can include a first light-shielding layer 4 and a second light-shielding layer 6.

In a preferable implementation, a second light-shielding layer 6 can be disposed around the protective layer 5.

In a more preferable implementation, the second light-shielding layer 6 is in a hollow structure, and is disposed around the protective layer 5 and connected to the protective layer 5 by an inlaid manner.

In a preferable implementation, the top of the second light-shielding layer 6 and the top of protective layer 5 are located at the same horizontal plane; the thickness of the second light-shielding layer 6 and the thickness of the protective layer 5 are substantially the same; the lateral sides of the second light-shielding layer 6 are flush with the LED light source 1; a horizontal distance between outer and inner surfaces of a lateral side of the second light-shielding layer 6 along a horizontal direction parallel to the ground is greater than a difference between the lengths of the quantum-dot photoresist layer 2 and the LED light source 1.

The material of the second light-shielding layer 6 of the present invention is not particularly limited, and various light-shielding materials well known to one of ordinary skill in the art can be used in the present invention; for example, the material of the second light-shielding layer can be polyacrylate material containing 30˜70 wt % of carbon black.

In a preferable implementation, the first light-shielding layer 4 can be disposed around the LED light source 1.

In a preferable implementation, the first light-shielding layer 4 is connected to the LED light source 1, the barrier layer 3 and the second light-shielding layer 6 in sequential order.

In a preferable implementation, a height of the first light-shielding layer 4 is not less than a sum of the heights of the quantum-dot photoresist layer 2 and the LED light source 1.

The height of each of the first light-shielding layer 4, the quantum-dot photoresist layer 2 and the LED light source 1 is defined as a distance from a top to a bottom thereof in a direction perpendicular to the ground.

In the present invention, the material of the first light-shielding layer 4 of the present invention is not particularly limited, and various light-shielding materials well known to one of ordinary skill in the art can be used in the present invention; for example, the material of the first light-shielding layer 4 can be polyacrylate material containing 30˜70 wt % of titanium dioxide.

The second aspect of the present invention is to provide a packaging method of quantum-dot light-emitting diode, and the packing method includes a step of packaging the structure of one of the above-mentioned quantum-dot light emitting diodes.

The present invention uses the quantum-dot photoresist layer instead of conventional organic silicone resin and epoxy resin, so that the property of the quantum-dot photoresist layer can be adjusted by the barrier layer and the light shielding layer, to improve the solids content of the quantum dots in the quantum-dot photoresist layer, and reduce thermal expansion coefficient.

The present invention uses yellow light technology to manufacture the quantum-dot photoresist light-emitting layer, to limit the size relationship between the light exit area of the LED light source and the light emitting area of the quantum-dot photoresist layer, so that the side space of the quantum-dot photoresist layer and the LED light source can be used to support the barrier material coated in sequential process. The quantum-dot photoresist layer having thickness lower than 20 μm and specific materials can decrease the step difference between the quantum-dot photoresist layer and the light exit surface of the LED light source, so as to improve coating property of the barrier material and make sure that the coating of the barrier material can be implemented by dry coating or wet coating and the barrier material is not easy to crack due to thermal expansion and contraction, thereby preventing air leakage and oxidation and increasing the successful rate of side packaging. The structure at the specific junction of the quantum-dot photoresist layer and the LED light source can also be adjusted through the yellow light process and material of the quantum-dot photoresist layer, so as to improve the side coverage of the barrier material and make the barrier material be more easily coated in sequential process, thereby increasing process reliability and extend material reliability.

In an embodiment, the quantum-dot light emitting diode of the present invention can include the second light-shielding layer disposed on the barrier material, to solve the light leakage problem caused by size difference between the light exit area of the LED light source and the light emitting area of the quantum-dot photoresist layer. In an embodiment, the periphery of the LED light source and the barrier layer can be enclosed by the first light-shielding layer, so as to realize the front-side single-sided luminous design, to increase the front-side emission efficiency.

Embodiment

The technical solution of the present invention will be described in detail below with reference to embodiments and drawings; however, the scope of the present invention is not limited to the following embodiments and drawings.

### First Embodiment

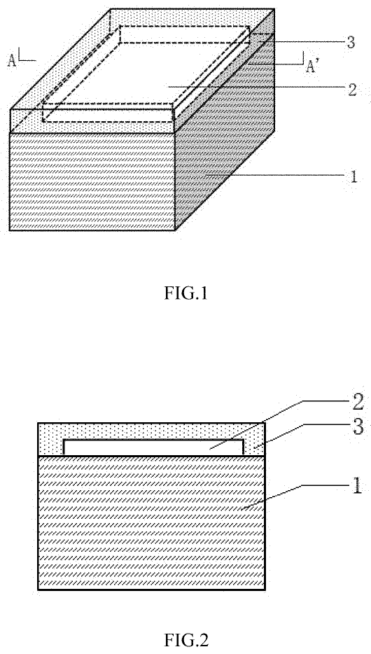

The first embodiment provides a quantum-dot light emitting diode, as shown in FIG. 1, the quantum-dot light emitting diode can include in sequential order from bottom to top, a LED light source 1, a quantum-dot photoresist layer 2 and a barrier layer 3. The LED light source 1, the quantum-dot photoresist layer 2, and the barrier layer 3 are bonded and fixedly connected to each other. The LED light source 1 is in a square shape and emits blue light with wavelength of 450 nm, and the efficiency of the LED light source 1 is 18.01 m/W at 20 mA.

The quantum-dot photoresist layer 2 is disposed on a central portion of a top of the LED light source 1, and the thickness of the quantum-dot photoresist layer 2 is 3.8 μm. The length of the quantum-dot photoresist layer 2 is smaller than the length of the LED light source 1 by 30 μm, and the width of the quantum-dot photoresist layer 2 is smaller than the width of the LED light source 1 by 30 μm. The edge structure at the junction of the quantum-dot photoresist layer 2 and the LED light source 1 is a perpendicular structure, as shown in FIG. 2. The quantum-dot photoresist layer 2 includes quantum dots and photoresist material, the weight ratio of the quantum dots to the photoresist material is 1:12; the quantum dots in the quantum-dot photoresist layer 2 is a combination of green quantum dots and red quantum dots, and the weight ratio of the green quantum dots to the red quantum dots is 2:1. The quantum dot is in a core-shell structure; the quantum dot contains 1.5 parts of CdSe, 2.8 parts of ZnS, and 0.6 parts of octadecylamine. The photoresist material is the polyacrylate material which contains 9 parts of methyl methacrylate, 11 parts of acrylic resin, 65 parts of propylene glycol methyl ether acetate, 1.5 parts of 2-benzyl-2-dimethylamino-1-(4-morpholinephenyl)) methyl ethyl ketone, and 3 parts of TiO2. The acrylic resin is BASF acrylic resin 7536, and the particle size of the TiO2 is 150 nm. The preparation method of the quantum-dot photoresist layer 2 includes the following steps of adding the quantum dot, the scatterer, the acrylate monomer, the acrylic resin and the photoinitiator into the solvent, blending and stirring uniformly the mixture at room temperature, and coating the mixture to obtain the quantum-dot photoresist layer.

The quantum-dot photoresist layer 2 is inlaid at a central portion of a bottom of the barrier layer 3. The barrier layer 3 is disposed on a central portion of a top of the LED light source 1 by blade coating method. The shape and size of the barrier layer 3 are substantially the same as the shape and size of the top of the LED light source 1, thickness of the barrier layer 3 is 1000 nm. The material of the barrier layer 3 is inorganic barrier material, such as SiO2.

### Second Embodiment

The second embodiment provides a quantum-dot light emitting diode, as shown in FIG. 3; the specific implementation of the second embodiment is similar to that of the first embodiment, the difference between the first embodiment and the second embodiment is that the edge structure at the junction of the quantum-dot photoresist layer 2 and the LED light source 1 in the second embodiment is an inclined structure.

### Third Embodiment

The third embodiment provides a quantum-dot light emitting diode, as shown in FIG. 4; the specific implementation of the third embodiment is similar to that of the first embodiment, the difference between the first embodiment and the third embodiment is that the edge structure at the junction of the quantum-dot photoresist layer 2 and the LED light source 1 in the third embodiment is a convex circular-arc structure.

### Fourth Embodiment

The fourth embodiment provides a quantum-dot light emitting diode, as shown in FIG. 5; the specific implementation of the fourth embodiment is similar to that of the first embodiment, the difference between the first embodiment and the fourth embodiment is that the edge structure at the junction of the quantum-dot photoresist layer 2 and the LED light source 1 in the fourth embodiment is a concave circular-arc structure.

### Fifth Embodiment

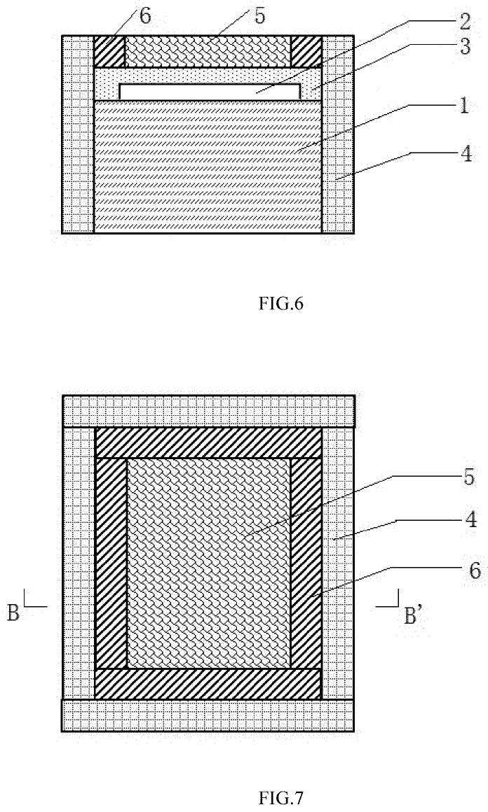

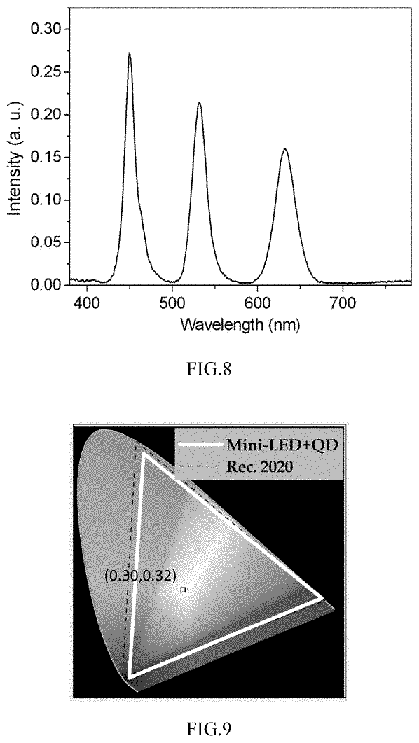

The fifth embodiment provides a quantum-dot light emitting diode, as shown in FIGS. 6 and 7; the specific implementation of the fifth embodiment is similar to that of the first embodiment, the difference between the first embodiment and the fifth embodiment is that, in the fifth embodiment, the protective layer 5 is disposed on a central portion of the top of the barrier layer 3, the thickness of the protective layer 5 is 30 μm, and the material of the protective layer 5 is SiO2.

Furthermore, the fifth embodiment includes a second light-shielding layer 6 disposed around the protective layer 5, and the second light-shielding layer 6 is in a hollow structure and disposed around the protective layer 5 through the inlaying connection method. The top of the second light-shielding layer 6 and the top of the protective layer 5 are located at the same horizontal plane; the thickness of the second light-shielding layer 6 and the thickness of the protective layer 5 are substantially the same; the lateral sides of the second light-shielding layer 6 are flush with the LED light source 1. The horizontal distance between the outer and inner surfaces of a side of the second light-shielding layer 6 is 35 μm along a horizontal direction parallel to the ground. The material of the second light-shielding layer 6 is acrylic photoresist material (such as polymethyl methacrylate) containing 50 wt % of carbon black.

The first light-shielding layer 4 is disposed around the LED light source 1. The first light-shielding layer 4 is connected to the LED light source 1, the barrier layer 3 and the second light-shielding layer 6, in sequential order. The top of the first light-shielding layer 4 and the second light-shielding layer 6 are located at the same horizontal plane; the material of the first light-shielding layer 4 is acrylic photoresist material (such as polymethyl methacrylate) containing 50 wt % of titanium dioxide (TiO2).

Performance Test

The white-point coordinate CIE(x, y) of the white quantum-dot LED measured by the integrating sphere is (0.279, 0.285), and the white quantum-dot LED has luminance efficiency of 80 lm/W and external quantum efficiency of 55%. The quantum-dot light emitting diode of the fifth embodiment combined with a wide color gamut color filter (CF-86) is measured to calculate the RGB CIE 1931 coordinate points as R(0.686, 0.306), G(0.171, 0.751) and B(0.150, 0.067), and the white point coordinate after CF is (0.30, 0.32). According to calculation result, the color gamut of the quantum-dot light emitting diode of the fifth embodiment can reach about 90% Rec. 2020.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A quantum-dot light emitting diode (LED) comprising, in sequential order from bottom to top, a LED light source, a quantum-dot photoresist layer and a barrier layer.

2. The quantum-dot light emitting diode according to claim 1, wherein the quantum-dot photoresist layer has a thickness lower than 20 μm.

3. The quantum-dot light emitting diode according to claim 1, wherein a length of the quantum-dot photoresist layer is smaller than a length of the LED light source by 0.1 μm to 100 μm, and a width of the quantum-dot photoresist layer is smaller than a width of the LED light source by 0.1 μm to 100 μm.

4. The quantum-dot light emitting diode according to claim 3, wherein an edge structure at junction of the quantum-dot photoresist layer and the LED light source is one of a perpendicular structure, an inclined structure, a circular-arc structure and a combination thereof

5. The quantum-dot light emitting diode according to claim 1, wherein the quantum-dot photoresist layer comprises quantum dots and photoresist material, and a weight ratio of the quantum dots to the photoresist material is in a range of 1:2 to 1:100.

6. The quantum-dot light emitting diode according to claim 1, wherein the quantum-dot photoresist layer is inlaid in the barrier layer.

7. The quantum-dot light emitting diode according to claim 1, further comprising a protective layer disposed on the barrier layer.

8. The quantum-dot light emitting diode according to claim 7, further comprising a second light-shielding layer disposed around the protective layer.

9. The quantum-dot light emitting diode according to claim 8, further comprising a first light-shielding layer disposed around the LED light source, wherein the first light-shielding layer is connected to the LED light source, the barrier layer and the second light-shielding layer in sequential order.

10. A packaging method of quantum-dot light-emitting diode, comprising:
packaging a quantum-dot light emitting diode which comprises, in sequential order from bottom to top, a LED light source, a quantum-dot photoresist layer and a barrier layer.

11. The packaging method according to claim 10, wherein the quantum-dot photoresist layer has a thickness lower than 20 μm.

12. The packaging method according to claim 10, wherein a length of the quantum-dot photoresist layer is smaller than a length of the LED light source by 0.1 μm to 100 μm, and a width of the quantum-dot photoresist layer is smaller than a width of the LED light source by 0.1 μm to 100 μm.

13. The packaging method according to claim 12, wherein an edge structure at junction of the quantum-dot photoresist layer and the LED light source is one of a perpendicular structure, an inclined structure, a circular-arc structure and a combination thereof.

14. The packaging method according to claim 10, wherein the quantum-dot photoresist layer comprises quantum dots and photoresist material, and a weight ratio of the quantum dots to the photoresist material is in a range of 1:2 to 1:100.

15. The packaging method according to claim 10, wherein the quantum-dot photoresist layer is inlaid in the barrier layer.

16. The packaging method according to claim 10, wherein the quantum-dot light emitting diode further comprises a protective layer disposed on the barrier layer to be packaged.

17. The packaging method according to claim 16, wherein the quantum-dot light emitting diode further comprises a second light-shielding layer disposed around the protective layer to be packaged.

18. The packaging method according to claim 17, wherein the quantum-dot light emitting diode further comprises a first light-shielding layer disposed around the LED light source to be packaged, wherein the first light-shielding layer is connected to the LED light source, the barrier layer and the second light-shielding layer in sequential order.
